(19) United States
(12) Patent Application Publication
(10) Pub. No.: US 2026/0197965 A1
(43) Pub. Date: Jul. 9, 2026

(54) FAN ASSEMBLY FOR AUTOMATED ASSEMBLING PROCESS

(71) Applicant: DELTA ELECTRONICS, INC., Taoyuan City (TW)

(72) Inventors: Wen-Chuan LO, Taoyuan City (TW); Chia-Hsiong HUANG, Taoyuan City (TW)

(21) Appl. No.: 19/176,084

(22) Filed: Apr. 10, 2025

(30) Foreign Application Priority Data
Jan. 7, 2025 (CN) 202510021233.8

(51) Int. Cl. H05K 7/20; H01R 12/81; H01R 43/26

(52) U.S. Cl. CPC H05K 7/20172; H01R 12/81; H01R 43/26

(57) ABSTRACT

A fan assembly includes a chassis, a bracket seat, a flexible board structure, and a fan set. The bracket seat is arranged in the chassis and includes a frame body and a pair of elastic arms. An insertion slot is defined between the pair of elastic arms and the frame body. The flexible board structure includes a flexible circuit board, a connector, and a stiffener. The flexible board structure is configured to be moved by a robot arm, and the stiffener is secured by the elastic arms to position the connector in the insertion slot. The fan set includes a fan and a fan socket set. The fan socket set is configured to be moved by a robot arm to connect to the connector.

### BACKGROUND OF THE DISCLOSURE

### Technical Field

The technical field relates to a fan assembly, and particularly to a fan assembly for an automated assembly process.

### Description of Related Art

In the related art, the cooling fan is usually installed in the chassis by manual operation, and the fan is installed inside the chassis with screws, fasteners, or other fixing accessories. Since the fan needs to be installed precisely, manual operation often encounters issues such as inaccurate positioning, difficulty in securing, or inconvenient force application due to narrow installation space. This makes it difficult to easily and accurately install the fan inside the chassis, which increases the time and difficulty of personnel operation and reduces production efficiency.

Furthermore, when the cooling fan is positioned in the case, the wires of the cooling fan usually need to be manually organized and secured to prevent them from colliding with the fan blades. However, due to the limited space inside the chassis, the wires are easily entangled, and the length of the cables complicates the management process and results in inconvenience in cable management. This may affect the cooling efficiency of the fan and the stability of the system.

In view of the above drawbacks, the inventor proposes this disclosure based on his expert knowledge and elaborate researches in order to solve the problems of related art.

### SUMMARY OF THE DISCLOSURE

This disclosure provides a fan assembly in which the fan set is assembled by an automated assembling process to improve production efficiency.

This disclosure provides a fan assembly for an automated assembling process to achieve the electrical connection between the fan set and the flexible board structure while simultaneously completing the cable management process.

This disclosure is a fan assembly including a chassis, a bracket seat, a flexible board structure, and a fan set. The bracket seat arranged in the chassis includes a frame body and a pair of elastic arms connected to the frame body. An insertion slot is defined between the pair of elastic arms and the frame body define. The flexible board structure includes a flexible circuit board, a connector connected to the flexible circuit board, and a stiffener disposed on the connector. The flexible board structure is drove by a robot arm to be moved to the bracket seat, and the stiffener is secured by the pair of elastic arms to position the connector in the insertion slot. The fan set is disposed in the chassis and located on one side of the bracket seat. The fan set includes a fan and a fan socket set coupled to one side of the fan. The fan socket set is drove by the robot arm to be connected to the connector.

In one embodiment of this disclosure, the frame body includes a frame plate and a pair of legs protruding outward from the frame plate. The pair of elastic arms is located on two sides of the frame plate opposite to each other. The frame body is combined with the chassis through a fastening element passing through each of the legs.

In one embodiment of this disclosure, the flexible board structure further includes a double-sided adhesive tape, and the flexible circuit board is attached to the chassis through the double-sided adhesive tape.

In one embodiment of this disclosure, the flexible circuit board includes a plug section equipped with the connector, and the plug section is shaped in a Y-shape.

In one embodiment of this disclosure, the fan set further includes a fan seat and a fan bracket. The fan is accommodated in the fan seat, and the fan bracket is coupled to one side of the fan seat.

In one embodiment of this disclosure, the fan set further includes a plurality of shock-absorbing rubbers, and the shock-absorbing rubbers penetrate the fan bracket and are combined with the fan seat.

In one embodiment of this disclosure, the fan socket set includes a plurality of wires, a socket, and a winding board. One ends of the wires are connected to the fan, and other ends of the wires are connected to the socket. The winding board is attached to the outer surface of the fan seat. The wires are wound around the winding board and the socket is combined with the winding board.

In one embodiment of this disclosure, the fan socket set further includes a pressing plate. One side of the pressing plate is engaged with the winding board, and another side of the pressing plate is secured to the fan bracket to press the wires.

In one embodiment of this disclosure, the fan socket set further includes a plurality of wires, a socket, and a winding board. One ends of the wires are connected to the fan, and other ends of the wires are connected to the socket. One side of the winding board is connected to the fan bracket, and another side of the winding board protrudes from the outer surface of the fan seat. The winding board is wound with the wires and combined with the socket.

In one embodiment of this disclosure, a socket groove is defined on the outer surface of the fan seat. The fan socket set further includes a plurality of wires and a socket. One ends of the wires are connected to the fan, and other ends of the wires are connected to the socket. The socket is arranged in the socket groove.

In comparison with the related art, the chassis of this disclosure is designed to be equipped with a bracket seat on one side of the fan set, and a flexible board structure and a fan set are also disposed therein. The flexible board structure is provided with a stiffener on one side of the connector. When the flexible board structure is moved to the bracket seat by a robot arm, the stiffener of the flexible board structure may spread apart the pair of elastic arms and be clamped by the elastic arms to allow the connector to fit into the slot and be positioned. Additionally, the fan socket set of this disclosure, which has the winding board wound with wires and combined with the socket, may facilitate the insertion of the socket of the fan socket set into the connector mounted on the mounting bracket when the robotic arm is moving the fan assembly. This achieves the electrical connection between the fan assembly and the flexible board structure while simultaneously completing the cable management. Therefore, the automated assembling process and convenience may be realized.

### BRIEF DESCRIPTION OF THE DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 depicts a perspective schematic view of the fan assembly for an automated assembly process according to this disclosure.

FIG. 2 depicts an assembly schematic view of the fan set according to this disclosure.

FIG. 3 depicts a connecting schematic view of the fan socket set and flexible board structure according to this disclosure.

FIG. 4 depicts a perspective exploded view of the bracket seat and the flexible board structure according to this disclosure.

FIG. 5 depicts a perspective exploded view of the fan set and the fan socket set according to this disclosure.

FIG. 6 and FIG. 7 depict another embodiment of the fan assembly for an automated assembly process according to this disclosure.

FIG. 8 and FIG. 9 depict still another embodiment of the fan assembly for an automated assembly process according to this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

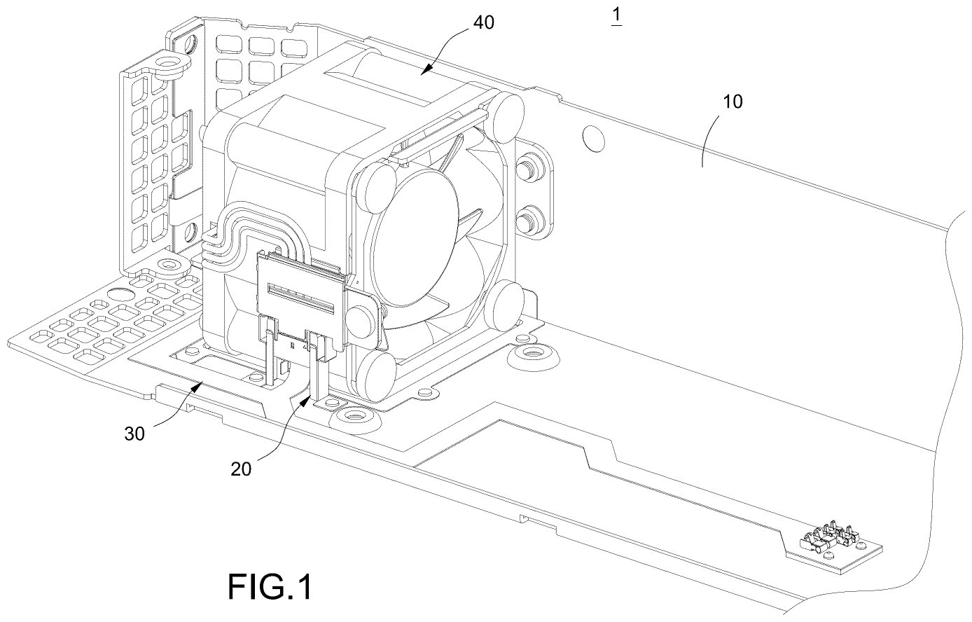

Please refer to FIG. 1, which depicts a perspective schematic view of the fan assembly for an automated assembly process according to this disclosure. The fan assembly 1 includes a chassis 10, a bracket seat 20, a flexible board structure 30, and a fan set 40. The bracket seat 20 is riveted to the chassis 10. The flexible board structure 30 is inserted to the bracket seat 20 through the assembly by the robot arm and is adhered to the chassis 10. Additionally, the fan set 40 is connected to the bracket seat 20 also by an automated assembling method using a robot arm and is fastened to the chassis 10. A more detailed description of the fan assembly 1 is as follows.

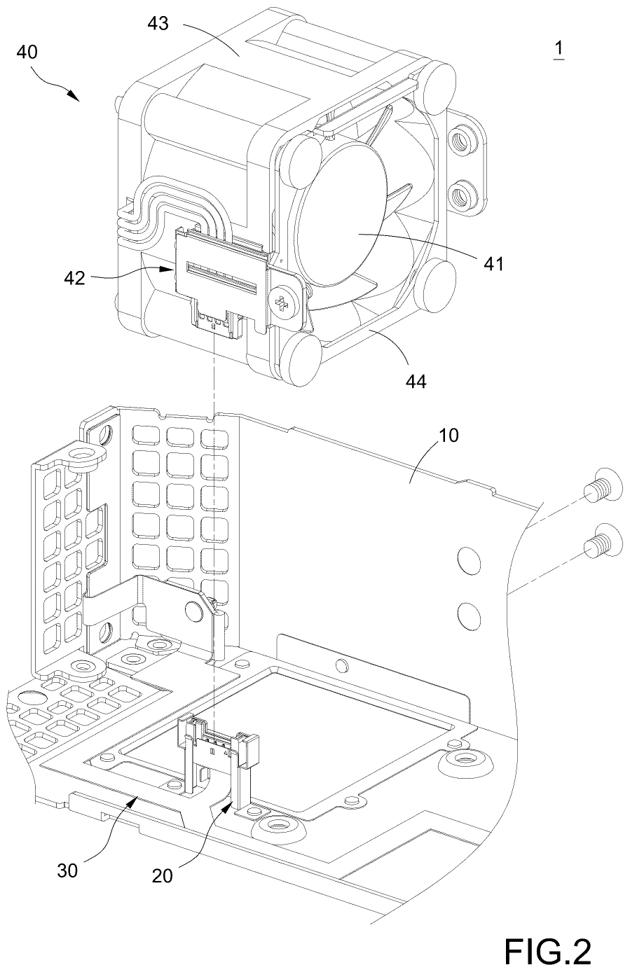

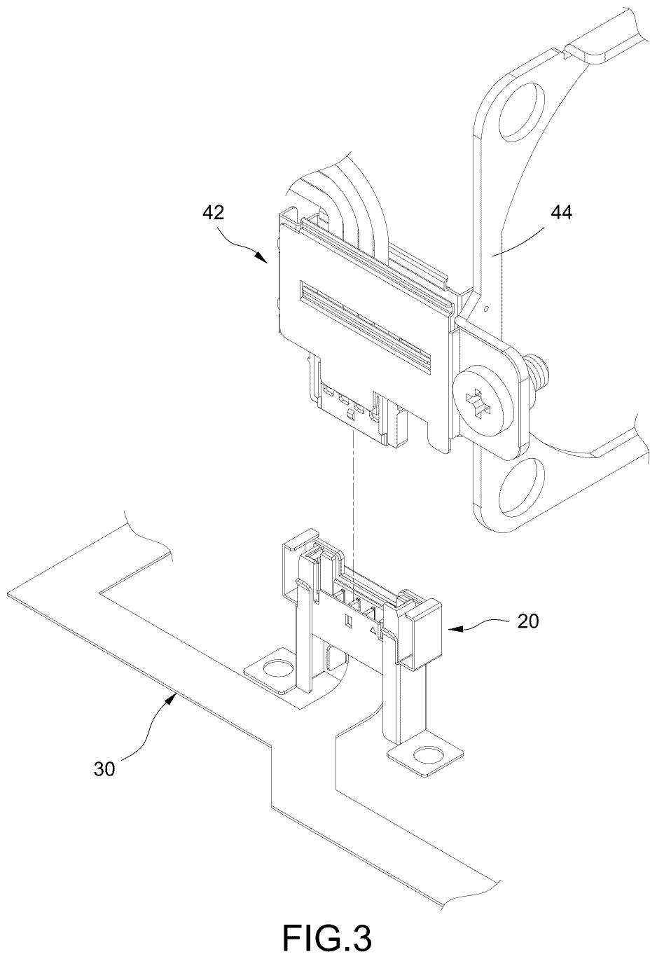

Please refer to FIG. 2 and FIG. 3, which depict an assembly schematic view of the fan set and a connecting schematic view of the fan socket set and flexible board structure according to this disclosure. The bracket seat 20 of this disclosure is connected with the flexible board structure 30 and is combined in the chassis 10. The fan set 40 is disposed in the chassis 10 and located on one side of the bracket seat 20. The fan set 40 includes a fan 41 and a fan socket set 42 coupled to one side of the fan 41. The fan socket set 42 is configured to be moved by a robot arm and connected to the flexible board structure 30 on the bracket seat 20.

In this embodiment, the fan set 40 further includes a fan seat 43 and a fan bracket 44. The fan 41 is accommodated in the fan seat 43, and the fan bracket 44 is combined on one side of the fan seat 43. The fan socket set 42 is arranged on one side of the fan bracket 44 and is placed on the outer surface of the fan seat 43.

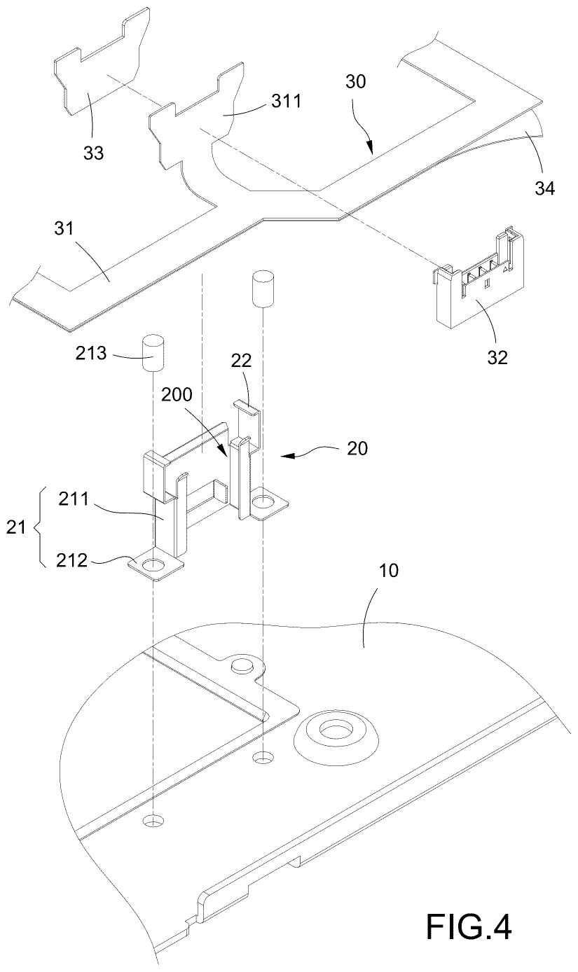

Please further refer to FIG. 4, which depicts a perspective exploded view of the bracket seat and the flexible board structure according to this disclosure. The bracket seat 20 of this disclosure includes a frame body 21 and a pair of elastic arms 22 connected to the frame body 21. The pair of elastic arms 22 and the frame body 21 define an insertion slot 200. Specifically, the frame body 21 includes a frame plate 211 and a pair of legs 212 protruding outward from the frame plate 211. Additionally, the pair of elastic arms 22 is located on opposite sides of the frame plate 211. The frame body 21 is combined with the chassis 10 through a fastening element 213 passing through each of the legs 212. In this embodiment, the fastening element 213 is a rivet. The frame body 21 is riveted to the chassis 10.

Moreover, the flexible board structure 30 includes a flexible circuit board 31, a connector 32 connected to the flexible circuit board 31, and a stiffener 33 disposed on the connector 32. The stiffener 33 is a plate made of a rigid material and is attached to one side of the flexible circuit board 31 to increase the strength of the flexible circuit board 31. Accordingly, when the flexible board structure 30 is moved by a robot arm to the bracket seat 20 and placed in position, the stiffener 33 may spread apart the pair of elastic arms 22 and be clamped by the pair of elastic arms 22 to allow the connector 32 to fit into the slot 200 and be positioned.

It should be noted that the flexible circuit board 31 includes a plug section 311 equipped with the connector 32. The plug section 311 is configured in a Y-shape to fit and support the connector 32. Additionally, the flexible board structure 30 further includes a double-sided adhesive tape 34, and the flexible circuit board 31 is attached to the inner bottom surface of the chassis 10 through the double-sided adhesive tape 34. In some embodiments, multiple nozzles are disposed in the assembly fixture to suck the flexible circuit board 31. Thus, the flexible circuit board structure 30 is moved to the positioning position by an automated assembling method.

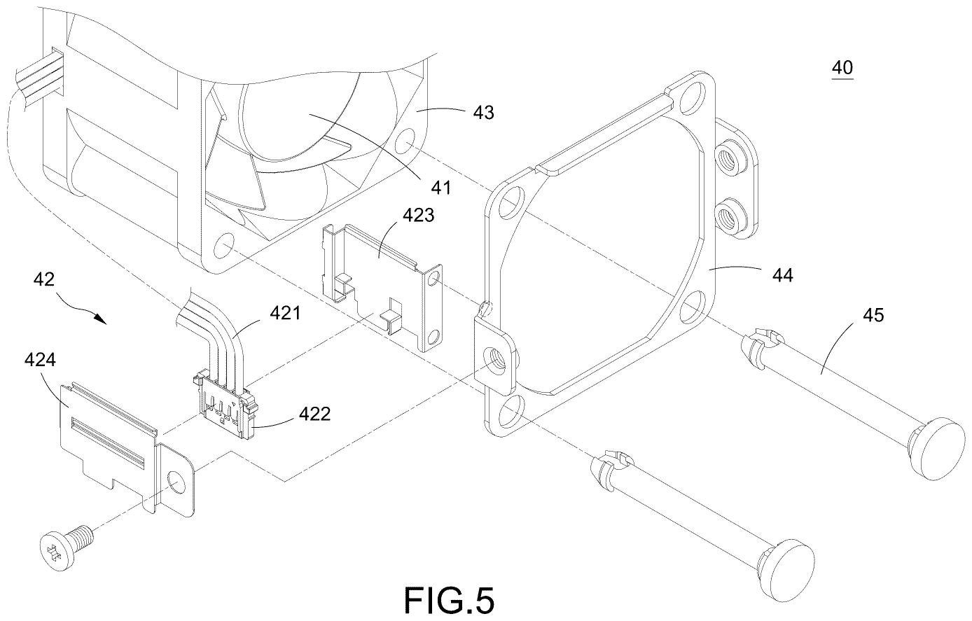

Please further refer to FIG. 5, which depicts a perspective exploded view of the fan set and the fan socket set according to this disclosure. In this embodiment, the fan assembly 1 includes a fan 41, a fan socket set 42, a fan seat 43, and a fan bracket 44, and further includes a plurality of shock-absorbing rubbers 45. The shock-absorbing rubbers 45 penetrate the fan bracket 44 and are combined with the fan seat 43 to absorb the vibrations generated by the operation of the fan 41.

Specifically, the fan socket set 42 includes a plurality of wires 421, a socket 422, and a winding board 423. One ends of the wires 421 are connected to the fan 41, and the other ends are connected to the socket 422. The winding board 423 is attached to the outer surface of the fan seat 43. The wiring board 423 is wound with the wires 421 and is combined with the socket 422 (refer to FIG. 2). It is worth noting that the fan socket set 42 further includes a pressing plate 424. One side of the pressing plate 424 is engaged with the winding board 423, and another side thereof is secured to the fan bracket 44 to press the wires 421 (further refer to FIG. 3).

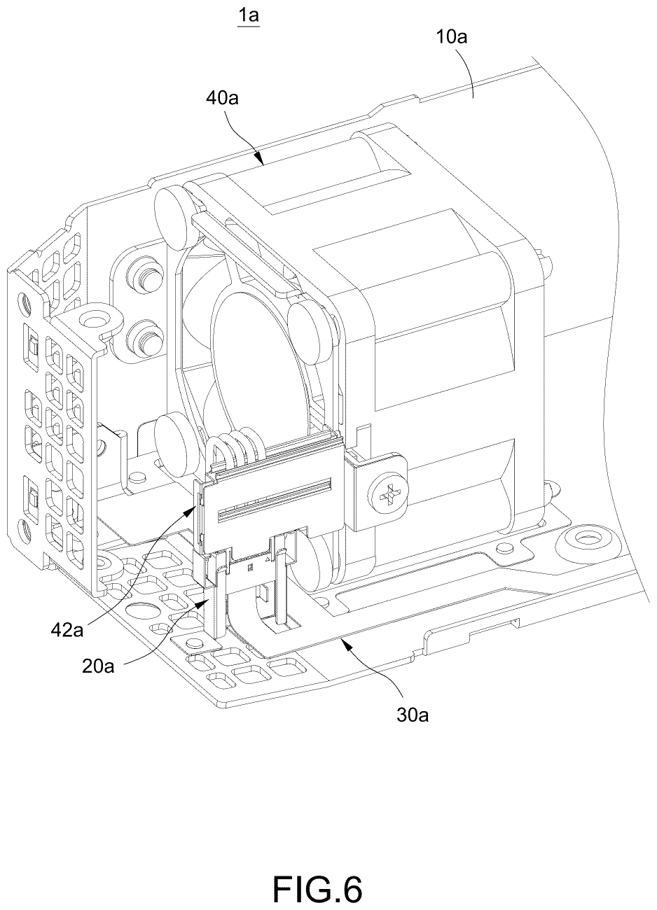

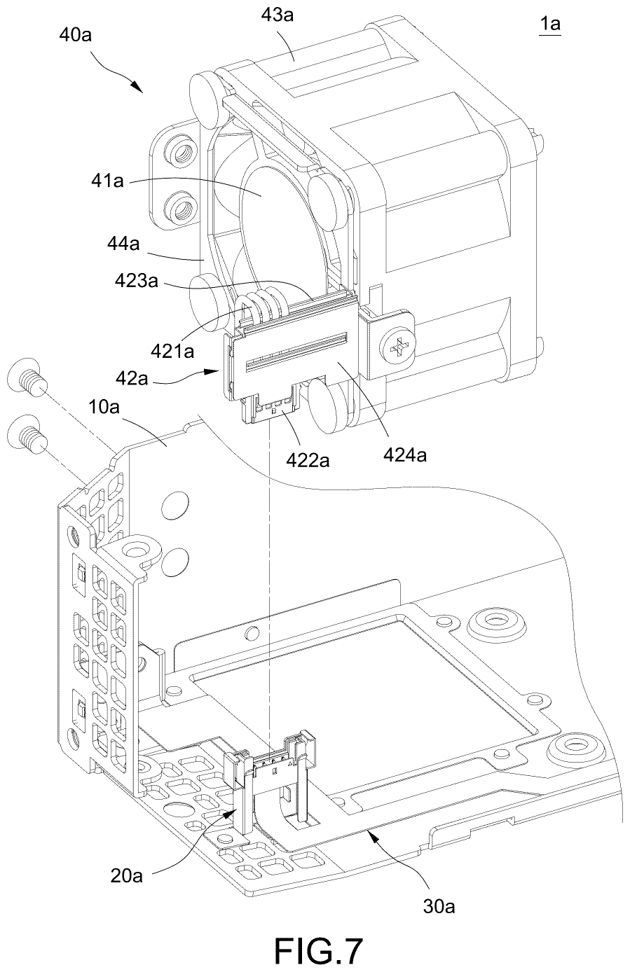

Please further refer to FIG. 6 and FIG. 7, which depict another embodiment of the fan assembly for an automated assembly process according to this disclosure. In this embodiment, the fan assembly 1a includes a chassis 10a, a bracket seat 20a, a flexible board structure 30a, and a fan set 40a. The bracket seat 20a and the flexible board structure 30a are combined with the chassis 10a in an automated assembling manner. The fan set 40a includes a fan 41a, a fan socket set 42a, a fan seat 43a, and a fan bracket 44a. The fan set 40a is disposed on one side of the bracket seat 20a also through an automated assembling method, and the fan socket set 42a is connected to the flexible board structure 30a through the bracket seat 20a. The difference in this embodiment compared to the previous embodiment lies in the implementation of the fan set 40a.

The fan socket set 42a includes a plurality of wires 421a, a socket 422a, a winding board 423a, and a pressing plate 424a. In this embodiment, one side of the winding board 423a is connected to the fan bracket 44a, and another side thereof protrudes from the outer surface of the fan seat 43a.

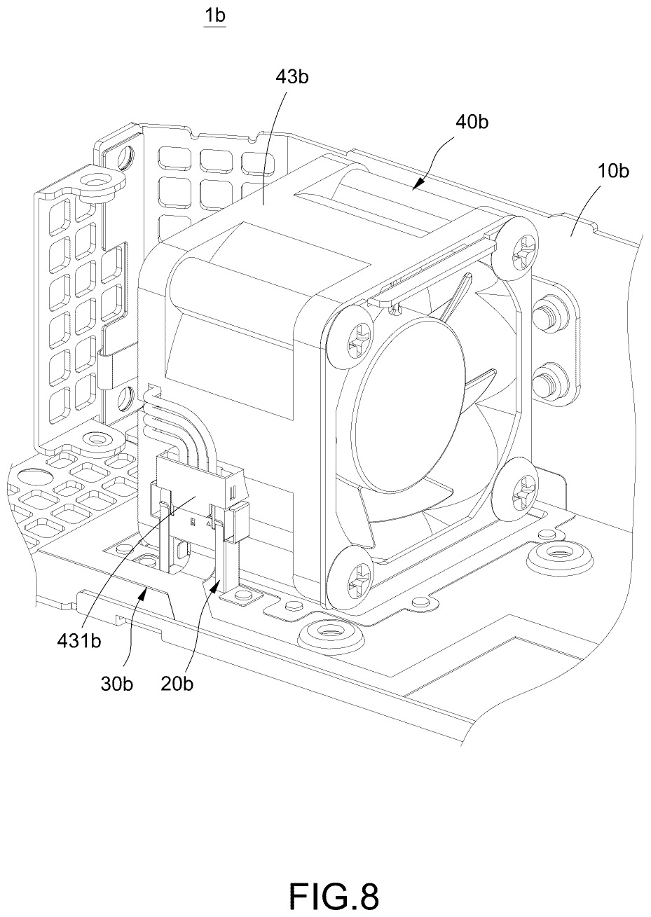

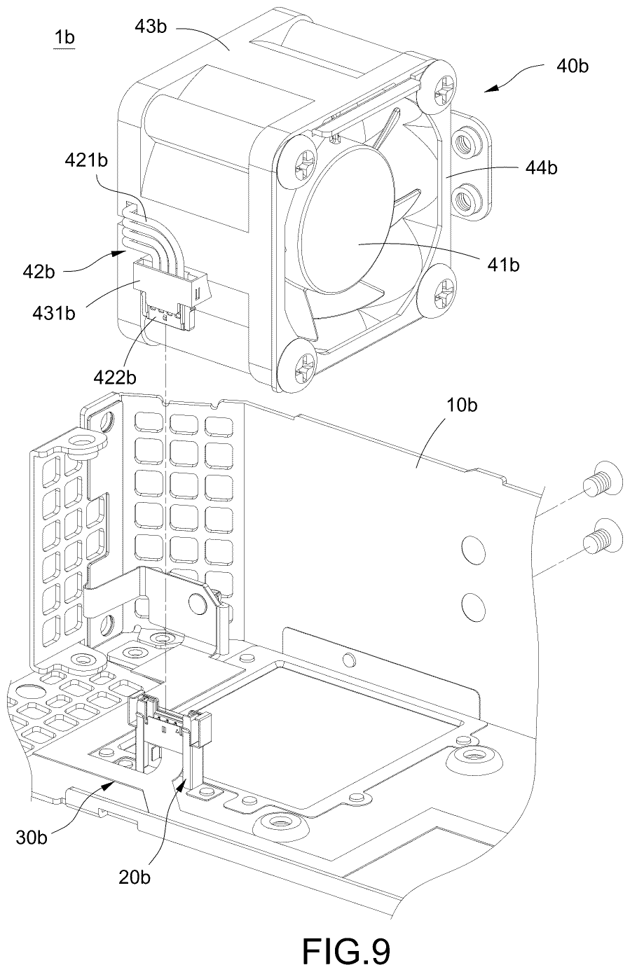

Please further refer to FIG. 8 and FIG. 9, which depict still another embodiment of the fan assembly for an automated assembly process according to this disclosure. In this embodiment, the fan assembly 1b includes a chassis 10b, a bracket seat 20b, a flexible board structure 30b, and a fan set 40b. The bracket seat 20b and the flexible board structure 30b are combined with the chassis 10b in an automated assembling manner. The fan set 40b includes a fan 41b, a fan socket set 42b, a fan seat 43b, and a fan bracket 44b. The fan set 40b is disposed on one side of the bracket seat 20b, also in an automated assembling manner, and the fan socket set 42b is connected to the flexible board structure 30b through the bracket seat 20b. The difference in this embodiment compared to the previous embodiment lies in the implementation of the fan set 40b.

The fan socket set 42b includes a plurality of wires 421b and a socket 422b. In this embodiment, a socket groove 431b is defined on the outer surface of the fan seat 43b. The socket 422b of the fan socket set 42b is arranged in the socket groove 431b to be connected to the flexible board structure 30b.

While this disclosure has been described by means of specific embodiments, numerous modifications and variations may be made thereto by those skilled in the art without departing from the scope and spirit of this disclosure set forth in the claims.

What is claimed is:

1. A fan assembly, comprising:
a chassis;
a bracket seat, arranged in the chassis, comprising a frame body and a pair of elastic arms connected to the frame body, wherein an insertion slot is defined between the pair of elastic arms and the frame body;
a flexible board structure, comprising a flexible circuit board, a connector connected to the flexible circuit board, and a stiffener disposed on the connector, wherein the flexible board structure is drove by a robot arm to be moved to the bracket seat, and the stiffener is secured by the pair of elastic arms to position the connector in the insertion slot; and
a fan set, disposed in the chassis and located on one side of the bracket seat, comprising a fan and a fan socket set coupled to one side of the fan, wherein the fan socket set is drove by the robot arm to be connected to the connector.

2. The fan assembly according to claim 1, wherein the frame body comprises a frame plate and a pair of legs protruding outward from the frame plate; the pair of elastic arms is located on two sides of the frame plate opposite to each other; and the frame body is combined with the chassis through a fastening element passing through each of the legs.

3. The fan assembly according to claim 1, wherein the flexible board structure further comprises a double-sided adhesive tape, and the flexible circuit board is attached to the chassis through the double-sided adhesive tape.

4. The fan assembly according to claim 1, wherein the flexible circuit board comprises a plug section equipped with the connector, and the plug section is shaped in a Y-shape.

5. The fan assembly according to claim 1, wherein the fan set further comprises a fan seat and a fan bracket, the fan is accommodated in the fan seat, and the fan bracket is coupled to one side of the fan seat.

6. The fan assembly according to claim 5, wherein the fan set further comprises a plurality of shock-absorbing rubbers, and the shock-absorbing rubbers penetrate the fan bracket and are combined with the fan seat.

7. The fan assembly according to claim 5, wherein the fan socket set comprises a plurality of wires, a socket, and a winding board; one ends of the wires are connected to the fan, and other ends of the wires are connected to the socket; the winding board is attached to an outer surface of the fan seat; and the wires are wound around the winding board and the socket is combined with the winding board.

8. The fan assembly according to claim 7, wherein the fan socket set further comprises a pressing plate; one side of the pressing plate is engaged with the winding board, and another side of the pressing plate is secured to the fan bracket to press the wires.

9. The fan assembly according to claim 5, wherein the fan socket set further comprises a plurality of wires, a socket, and a winding board; one ends of the wires are connected to the fan, and other ends of the wires are connected to the socket; one side of the winding board is connected to the fan bracket, and another side of the winding board protrudes from an outer surface of the fan seat, and the winding board is wound with the wires and combined with the socket.

10. The fan assembly according to claim 5, wherein a socket groove is defined on an outer surface of the fan seat; the fan socket set further comprises a plurality of wires and a socket; one ends of the wires are connected to the fan, and other ends of the wires are connected to the socket; and the socket is arranged in the socket groove.
